(19) United States
(12) Patent Application Publication
(10) Pub. No.: US 2025/0201294 A1
(43) Pub. Date: Jun. 19, 2025

(54) RANDOMIZED REFRESH OPERATIONS

(71) Applicant: Micron Technology, Inc., Boise, ID (US)

(72) Inventors: Michele Scaravilli, Munich (DE); Ken Choong Lim, Munich (DE); Matthias Herbst, Munich (DE)

(21) Appl. No.: 18/970,701

(22) Filed: Dec. 5, 2024

Related U.S. Application Data
(60) Provisional application No. 63/609,790, filed on Dec. 13, 2023.

(51) Int. Cl. G11C 11/406; G11C 11/4096

(52) U.S. Cl. CPC G11C 11/40622; G11C 11/40603; G11C 11/4096

(57) ABSTRACT

Methods, systems, and devices for randomized refresh operations are described. A memory system may perform refresh operations to refresh logic states stored in rows targeted by successive access operations based on sampling a random noise signal. For example, the memory system, or a host system, may implement a random noise generator configured to generate the random noise signal, and the random noise signal may be sampled to generate a random value. The random value may be mapped to a random row address, and rows adjacent to or nearby the random row may be refreshed. In some cases, the random noise generator may be implemented at the memory system, or at the host system and the random noise signal may be transmitted to the memory system. For example, the host system may perform a verification operation with the memory system prior to transmitting the random noise signal.

### CROSS REFERENCE

The present Application for Patent claims priority to U.S. Patent Application No. 63/609,790 by Scaravilli et al., entitled “RANDOMIZED REFRESH OPERATIONS,” filed Dec. 13, 2023, which is assigned to the assignee hereof, and which is expressly incorporated by reference in its entirety herein.

### TECHNICAL FIELD

The following relates to one or more systems for memory, including randomized refresh operations.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports randomized refresh operations in accordance with examples as disclosed herein.

FIGS. 2A, 2B, and 2C show examples of systems that supports randomized refresh operations in accordance with examples as disclosed herein.

FIGS. 3A and 3B show examples of a random noise signal diagram and a row address refreshing scheme that supports randomized refresh operations in accordance with examples as disclosed herein.

FIG. 4 shows an example of a process flow that supports randomized refresh operations in accordance with examples as disclosed herein.

FIG. 5 shows a block diagram of a memory system that supports randomized refresh operations in accordance with examples as disclosed herein.

FIG. 6 shows a flowchart illustrating a method or methods that support randomized refresh operations in accordance with examples as disclosed herein.

### DETAILED DESCRIPTION

A memory system may include one or more volatile memory arrays (e.g., associated with one or more volatile memory devices), each including rows of volatile memory cells (e.g., DRAM cells). In some cases, accessing (e.g., applying a voltage associated with an access operation) a row (e.g., an aggressor row) may cause voltage disturbances on nearby rows (e.g., victim rows), such that successively accessing the row may alter charges stored in memory cells of the nearby rows. Such successive accesses, which may be referred to as row hammering, may cause errors in the data stored to the nearby rows. In some cases, a bad actor (e.g., malware) may attempt to induce errors to the memory system by successively accessing rows of the one or more volatile memory arrays (e.g., a row hammer attack). In some examples, the bad actor may implement an algorithmic randomized attack to randomly select and access rows, thereby inducing errors at multiple rows across the one or more volatile memory arrays.

In some cases, a memory system may perform refresh operations (e.g., a row hammer refresh) to refresh logic states stored in rows targeted by successive access operations. For example, the memory system may identify successive access operations on an aggressor row, and refresh victim rows adjacent to the aggressor row (e.g., rows with a row address one above or one below the aggressor row address). In some examples, the memory system may implement one or more linear feedback shift registers (LFSRs) to randomize the refresh operations, which may counteract attacks from the bad actor. For example, the one or more LFSRs may generate a random value, which may be mapped to a row address of the one or more volatile memory arrays, such that victim addresses adjacent to the random row address may be refreshed.

However, the one or more LFSRs may be digital components configured to generate the random value based on an algorithm, which a bad actor could exploit. Thus, implementing the one or more LFSRs to randomize performing the refresh operations may be counteracted by the bad actor, enabling the bad actor to continue implementing an algorithmic randomized attack (e.g., based on an algorithm of the one or more LFSRs) to induce errors across the one or more volatile memory arrays. Accordingly, a system configured to mitigate algorithmic randomized attacks may be desirable.

A system configured to mitigate algorithmic randomized attacks is described herein. In accordance with examples as described herein, a memory system may perform refresh operations based on sampling a random noise signal. For example, the memory system (e.g., or a host system of the memory system) may implement a random noise generator configured to generate a random noise signal, and the random noise signal may be sampled to generate a random value. The random value may be mapped to a random row address of the one or more volatile memory arrays, and victim rows adjacent to or nearby the random row may be refreshed.

In some cases, the random noise generator may be an analog component configured to generate the random noise signal as an analog signal, which may be difficult for a bad actor to determine. In some examples, the random noise generator may be implemented at the memory system or at the host system, and the random noise signal (e.g., or the random value, or the random row address) may be transmitted to the memory system. In such examples, the host system may perform a verification operation (e.g., a handshake operation) with the memory system prior to transmitting the random noise signal. Implementing the random noise signal for randomizing refresh operations may counteract attacks from a bad actor, while preventing the bad actor from exploiting algorithmic refresh operations, among other advantages.

In addition to applicability in memory systems described herein, techniques for randomized refresh operations may be generally implemented to improve security and/or authentication features of various electronic devices and systems. As the use of electronic devices for handling private, user, or other sensitive information has become even more widespread, electronic devices and systems have become the target of increasingly frequent and sophisticated attacks. Further, unauthorized access or modification of data in security-critical devices such as vehicles, healthcare devices, and others may be especially concerning. Implementing the techniques described herein may improve the security of electronic devices and systems by randomizing performing refresh operations associated with row hammering, which may prevent or mitigate a bad actor from inducing errors on the electronic devices, among other benefits.

Features of the disclosure are illustrated and described in the context of systems and architectures. Features of the disclosure are further illustrated and described in the context of systems, a random noise signal diagram, a row address refreshing scheme, a process flow, and a flowchart.

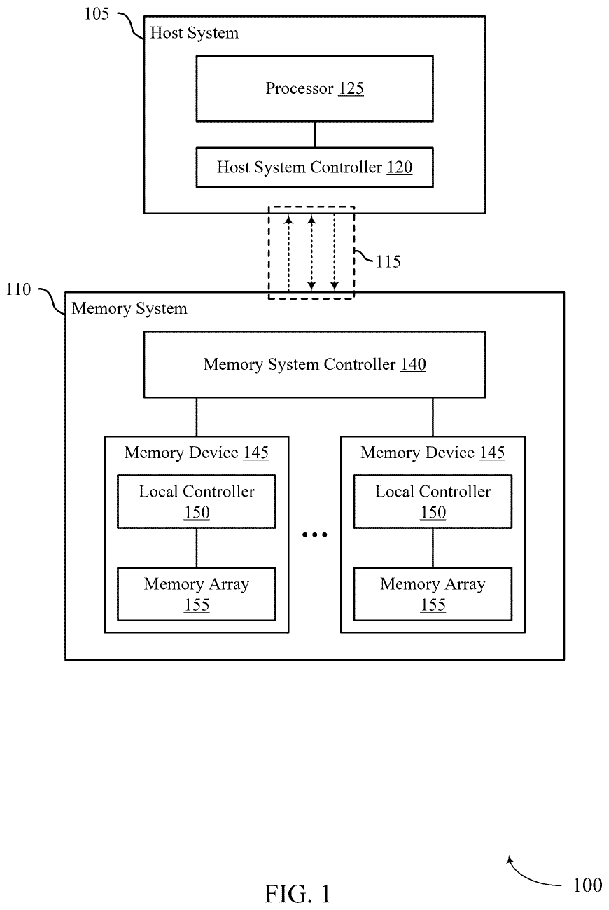

FIG. 1 illustrates an example of a system 100 that supports randomized refresh operations in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In accordance with examples as described herein, the one or more memory arrays 155 may be volatile memory arrays, each including rows of volatile memory cells (e.g., DRAM cells). The memory system 110 may perform refresh operations (e.g., row hammer refresh operations) to refresh logic states stored in rows targeted by successive access operations. In some cases, the memory system 110 may perform the refresh operations based on sampling a random noise signal. For example, the memory system 110 (e.g., or the host system 105) may include a random noise generator configured to generate a random noise signal, and the random noise signal may be sampled to generate a random value. The random value may be mapped to a row address of the one or more memory arrays 155, and victim rows adjacent to or nearby the row (e.g., the row address mapped to the random value) may be refreshed.

In some cases, the random noise generator may be an analog component configured to generate the random noise signal as an analog signal, which may be difficult for a bad actor to determine. In some examples, the random noise generator may be implemented at the memory system 110 or at the host system 105, and the random noise signal (e.g., or the random value, or the random row address) may be transmitted to the memory system 110. In some such examples, the host system 105 may perform a verification operation (e.g., a handshake operation) with the memory system 110 prior to transmitting the random noise signal. Implementing the random noise signal for randomizing refresh operations may counteract attacks from a bad actor, while preventing the bad actor from exploiting algorithmic refresh operations, among other advantages.

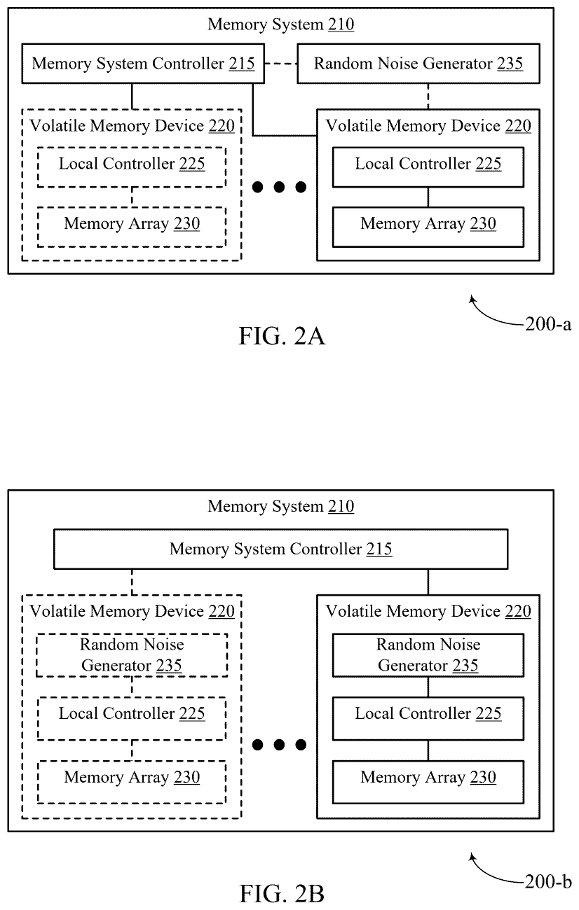

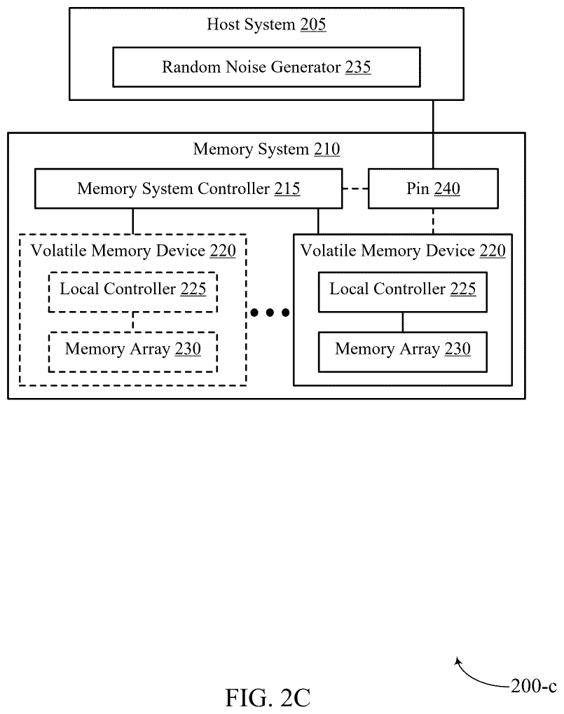

FIGS. 2A and 2B show examples of a system 200-a, a system 200-b, and a system 200-c that support randomized refresh operations in accordance with examples as disclosed herein. The system 200-a, the system 200-b, and the system 200-c may be examples of or implement aspects or operations of a system, which may be an example of a system 100, as described with reference to FIG. 1. For example, the system 200-a, the system 200-b, and the system 200-c may each implement a memory system 210, which may be an example of a memory system 110, as described with reference to FIG. 1. The system 200-a, the system 200-b, and the system 200-c may each be configured to perform refresh operations based on sampling and mapping a random noise signal to a row address of the system 200-a, the system 200-b, or the system 200-c.

The system 200-a, the system 200-b, and the system 200-c may each implement a memory system 210 including a memory system controller 215, which may be an example of a memory system controller 140, as described with reference to FIG. 1. The memory system controller 215 may be configured to control operations of the memory system 210, such as refresh operations. The memory system 210 may include one or more volatile memory devices 220 (e.g., DRAM devices), which may be examples of memory devices 145, as described with reference to FIG. 1. The one or more volatile memory devices 220 may each include a local controller 225 and one or more memory arrays 230, which may be examples of local controllers 150 and memory arrays 155, respectively, as described with reference to FIG. 1. The one or more memory array 230 may be volatile memory arrays (e.g., DRAM arrays) that each include one or more rows of volatile memory cells (e.g., DRAM cells).

The system 200-a, the system 200-b, and the system 200-c may each include one or more random noise generators 235 configured to generate a random noise signal. A random noise generator 235 may be an analog component configured to generate a random noise signal as an analog signal. In some cases, the random noise generator 235 may include one or more Chua circuits (e.g., based on resonators and non-linear elements), or amplification and digitalization circuitry for signals produced by noise sources (e.g., diodes or resistances). The random noise signal may be sampled to identify a value (e.g., a voltage value), which may be used to generate a corresponding random value (e.g., a random number). The random value may be mapped to a row address, which may be used to identify row addresses of adjacent rows, and the adjacent and/or nearby rows may be refreshed.

Regarding FIG. 2A, the system 200-a may be illustrative of a system in which the random noise generator 235 is implemented within the memory system 210. In some cases, the random noise generator 235 may be implemented in the memory system 210, where the memory system 210 is a dual in-line memory module (DIMM). In such examples, the random noise generator 235 may be coupled with the memory system controller 215. For example, the random noise generator 235 may be configured to output the random noise signal (e.g., or the random value) to the memory system controller 215, and the memory system controller 215 may use the random noise signal (e.g., or the random value) for identifying the random row address.

In other examples, the random noise generator 235 may be coupled with the one or more volatile memory devices 220. For example, the random noise generator 235 may be configured to output the random noise signal (e.g., or the random value) to the respective local controller 225, and the local controller 225 may use the random noise signal (e.g., or the random value) for identifying the random row address. In some cases, the random noise generator 235 (e.g., or multiple random noise generators) may be implemented in one or more of the volatile memory devices 220, where the volatile memory devices 220 are DRAM dies (e.g., DRAM chips).

Regarding FIG. 2B, the system 200-b may be illustrative of another system in which the random noise generator 235 is implemented within the memory system 210. In some cases, the random noise generator 235 may be implemented in the volatile memory device 220, where the volatile memory device 220 is a DRAM device (e.g., a DRAM die, a DRAM chip) implemented on a dual in-line memory module (DIMM) (e.g., the memory system 210). In such examples, a random noise generator 235 may be implemented in each volatile memory device 220, such that the memory system 210 may include multiple random noise generators 235. In some cases, each random noise generator 235 may be coupled with the memory system controller 215 or a respective local controller 225. For example, the random noise generator 235 may be configured to output the random noise signal (e.g., or the random value) to the local controller 225, and the local controller 225 may use the random noise signal (e.g., or the random value) for identifying the random row address.

Regarding FIG. 2C, the system 200-c may be illustrative of a system in which the random noise generator 235 is implemented within a host system 205 of the system 200-c. The host system 205 may be coupled with the memory system 210 and may be operable to perform operations (e.g., access operations) on the memory system 210. In some cases, the memory system 210 may include a pin 240, where the pin 240 may be configured to receive the random noise signal (e.g., or a random value or a random row address), or perform a verification operation (e.g., a handshake operation) with the host system 205. For example, the random noise generator 235 may generate the random noise signal, and the host system 205 may transmit the random noise signal to the memory system 210 via the pin 240.

In another example, the host system 205 may perform the verification operation with the memory system 210 via the pin 240, such that the pin 240 may communicate verification indications (e.g., codes, authentication information, handshake information, identification information) between the host system 205 and the memory system 210. For example, prior to transmitting the random noise signal to the memory system 210, the host system 205 may transmit a verification indication to the memory system 210 via the pin 240, and the memory system 210 may determine whether the verification indication satisfies one or more verification parameters. If the memory system 210 determines the verification indication is valid, the memory system 210 may accept the random noise signal via the pin 240. In some implementations, commands or indications to start and/or stop communicating the random noise signal (e.g., or timing parameters for communicating the random noise signal) may be similarly communicated via the pin 240.

Implementing the random noise generator 235 in the system 200-a, the system 200-b, and the system 200-c may enable increased security for the system 200-a, the system 200-b, and the system 200-c. For example, generating the random noise signal and mapping sampled points of the random noise signal to row addresses of the system 200-a, the system 200-b, or the system 200-c may counteract row hammering attacks from a bad actor. Further, because the random noise signal may be an analog signal, the bad actor may be less likely (or unable) to determine a pattern of randomization of the random noise signal, which the bad actor may otherwise use to perform the row hammering attacks.

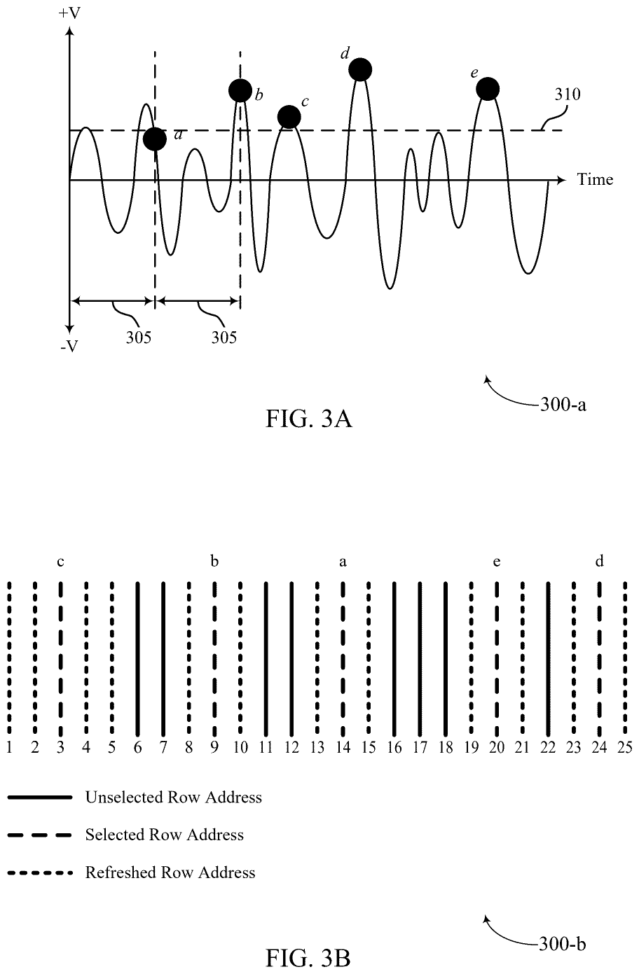

FIGS. 3A and 3B show examples of a random noise signal diagram 300-a and a row address refreshing scheme 300-b that supports randomized refresh operations in accordance with examples as disclosed herein. The random noise signal diagram 300-a and the row address refreshing scheme 300-b may illustrate aspects or operations of a system, which may be an example of a system 200-a, a system 200-b, or a system 200-c, as described with reference to FIGS. 2A, 2B, and 2C, respectively. For example, the random noise signal diagram 300-a illustrates a random noise signal, which may be an example of a random noise signal generated by the random noise generator 235 as described with reference to FIGS. 2A, 2B, and 2C. Likewise, the row address refreshing scheme 300-b may illustrate row addresses associated with one or more refresh operations, where the row addresses may correspond to rows of a volatile memory array, such as memory array 230, as described with reference to FIGS. 2A, 2B, and 2C.

With reference to FIG. 3A, the random noise signal diagram 300-a may illustrate a voltage and timing of a random noise signal with respect to a voltage axis (e.g., a y-axis) and a timing axis (an x-axis). As illustrated, the voltage axis may be bipolar, such that a voltage of the random noise signal may have a magnitude with a positive polarity and a negative polarity. However, in some cases, the random noise signal may have a magnitude that is only of the positive polarity or the negative polarity. The random noise signal diagram 300-a illustrates the voltage of the random noise signal over time, where the random noise signal is an analog signal with a random amplitude and random frequency. For example, the magnitude of the voltage of the random noise signal may vary randomly, and the period of the random noise signal may vary randomly, such that the random noise signal is not repetitive.

The random noise signal diagram 300-a also illustrates points at which the random noise signal is sampled. In some cases, the random noise signal may be sampled at consistent periods (e.g., based on a clock signaling). For example, the random noise signal may be sampled at every period 305 of a clock. However, in other cases, the random noise signal may be randomly sampled at random points (e.g., at random instances in time). In some cases, the random noise signal may be sampled each instance the random noise signal satisfies a voltage threshold 310. For example, the random noise signal may be sampled each time an amplitude of the random noise signal satisfies (e.g., is equal to or greater than) the voltage threshold 310. In some implementations, the random noise signal may be sampled each time an amplitude of a peak of the random noise signal satisfies the voltage threshold 310. In other implementations, the random noise signal may be sampled each time an amplitude of the random noise signal crosses the voltage threshold 310 (e.g., on a rising edge of the random noise signal, on falling edge of the random noise signal).

The random noise signal diagram 300-a shows an example in which the random noise signal is sampled at points a, b, c, d, and e in time. For example, points a and b may be sampled based on implementing a clock signaling with sampling intervals at every period 305 of the clock, such that points a and b may correspond to the amplitude of the random noise signal at periods 305. Conversely, points c, d, and e may be sampled based on implementing the voltage threshold 310, such that points c, d, and e may correspond to the amplitude of the random noise signal at instances in which the random noise signal satisfied the voltage threshold 310. In some cases, a value (e.g., a voltage value of the amplitude) of the random noise signal may be recorded for each sampled point of the random noise signal, and the value may be used to select a row address. In some implementations, the value may be stored to a register. Due to the random nature of the values, when the random values are mapped to the row address, a random row address is mapped for each sample. In some cases, the random row address may be selected based mapping the values to a number of activations or activation commands. For example, sampling the random noise signal at point a may yield a value which maps to 14 activations, such that after activating each row address prior to row address 14, the row address 14 may be selected. Likewise, sampling the random noise signal at point b may yield a value which maps to 9 activations, such that row address 9 may be selected. Such correspondence between signal points (e.g., point a) and a corresponding row address (e.g., row address 14) are for exemplary purposes, and each signal point may be mapped to any row address of a memory array.

With reference to FIG. 3B, the row address refreshing scheme 300-b illustrates refreshing the rows of the volatile memory array based on the sampled points a, b, c, d, and e. For illustrative clarity, the row addresses of the row address refreshing scheme 300-b are categorized as unselected row addresses, selected row addresses, and refreshed row addresses. The selected row addresses (e.g., aggressor row addresses) may be row addresses that map to a sampled point, and the refreshed row addresses (e.g., victim row addresses) may be the row addresses that are refreshed as a result of sampling the random noise signal. The refreshed row addresses are adjacent to or nearby the selected row addresses, such that each address that is numerically above or below (e.g., ±1, ±2, ±3, ±4, ±N, etc.) the selected row address may be refreshed row addresses.

In some cases, the refreshed row addresses may be a numerical distance (e.g., N) away from the selected row address, where N signifies a quantity of row addresses numerically above and below the selected row address. For example, when N is equal to 4, the refreshed row addresses may include the 4 row addresses numerically above (e.g., near or adjacent to in a first direction) the selected row address, and the 4 row addresses numerically below (e.g., near or adjacent to in a second direction) the selected row address. In some cases, the numerical distance may be referred to as a bounded refresh configuration and may be stored in a register. In some cases, N may also specify only the specific row addresses to refresh relative to the selected row address, such that when N is equal to 4, only the 4th row address numerically above the selected row address and only the 4th row address numerically below the selected row address may be refreshed (e.g., row addresses ±1, ±2, ±3 may not be refreshed). In some implementations, a value of N may be selected by a user, indicated from a host system (e.g., host system 205), or programmed (e.g., in read-only memory) during manufacturing. The unselected row addresses do not correspond to a sampled point, nor are the unselected row addresses adjacent to a selected row address.

The row addresses adjacent to or nearby the row addresses corresponding to the sampled point may be identified (e.g., selected) for a refresh operation. That is, the rows corresponding to the adjacent or nearby row addresses may be refreshed as a result of mapping the sampled point to the corresponding row address. For example, sampling the random noise signal at point a maps to row address 14, thus the rows corresponding to row addresses 13 and 15 may be refreshed. Likewise, sampling the random noise signal at point b maps to row address 9, thus the rows corresponding to row addresses 8 and 10 may be refreshed. In some cases, the selected row address may be stored in a content addressable memory (CAM) until a refresh command is received, then the refreshed row addresses may be refreshed. In some implementations, additional row addresses (e.g., besides or in addition to the adjacent row addresses) nearby the selected row address may be refreshed.

In some such implementations, the system 200-a, the system 200-b, or the system 200-c may dynamically configure the quantity of additional row addresses (e.g., ±1, ±2, ±3, ±4, ±N, etc.) nearby the selected row address may be refreshed. For example, sampling the random noise signal at point c maps to row address 3, thus the rows corresponding to row addresses 1, 2, 4, and 5 may be additionally or alternatively refreshed. In some examples, the system 200-a or the system 200-b may determine the quantity of additional row addresses to refresh based on a parameter or a threshold (e.g., N row addresses). In some implementations, the selected row address may additionally, or alternatively, be refreshed. For example, sampling the random noise signal at point d maps to row address 24, thus the row corresponding to row address 24 may be refreshed, or the rows corresponding to row addresses 23, 24, and 25 may be refreshed.

Implementing the random noise signal, as illustrated in the random noise signal diagram 300-a, and the row address refreshing scheme 300-b may enable increased security for a system, such as the system 200-a, the system 200-b, and the system 200-c. For example, generating the random noise signal and mapping sampled points of the random noise signal to row addresses may counteract row hammering attacks (e.g., successively activating same row addresses) from a bad actor. In some examples, the bad actor may be a cybercriminal, malware, spyware, ransomware, or a targeted attack configured to induce wear on the system 200-a, the system 200-b, or the system 200-c by performing the row hammering attacks. Further, because the random noise signal may be an analog signal, the bad actor may be less likely (or unable) to determine a pattern of randomization of the random noise signal, which the bad actor may otherwise use to perform the row hammering attacks.

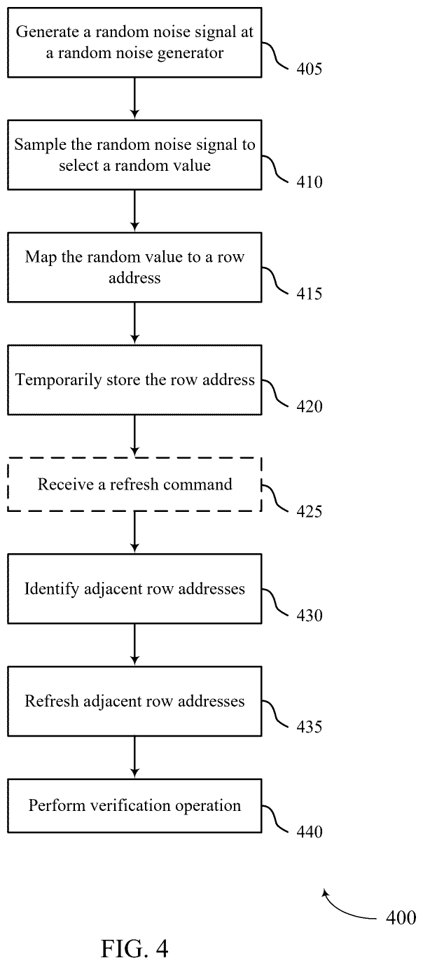

FIG. 4 shows an example of a process flow 400 that supports randomized refresh operations in accordance with examples as disclosed herein. The process flow 400 may illustrate aspects or operations of a system, which may be an example of a system 200-a, a system 200-b, or a system 200-c, as described with reference to FIGS. 2A, 2B, and 2C. For example, the process flow 400 may be implemented by a host system 205 and/or a memory system 210, as described with reference to FIGS. 2A, 2B, and 2C. In the following description of the process flow 400, the methods, techniques, processes, and operations may be performed in different orders or at different times. Further, some operations may be left out of the process flow 400, or other operations may be added to the process flow 400.

Aspect of the process flow 400 described at the memory system 210 may be implemented by a memory system controller 215 or by the host system 205, as described with reference to FIGS. 2A, 2B, and 2C. Additionally, or alternatively, aspects of the process flow 400 may be implemented as instructions stored in memory (e.g., firmware). For example, the instructions, if executed by a controller (e.g., a processor, a host system controller, the memory system controller 215, a local controller 225), may cause the controller to perform the operations of the process flow 400. The process flow 400 may illustrate performing a randomized refresh operation based on a random noise signal.

At 405, a random noise generator 235 may generate a random noise signal, as described with reference to FIGS. 2A, 2B, and 2C. In some cases, the random noise generator 235 may be implemented within the memory system 210. For example, the random noise generator 235 may be implemented in a DIMM associated with the memory system 210, or within a volatile memory device 220 (e.g., a DRAM device, a DRAM die), as described with reference to FIGS. 2A and 2B. In some such examples, the random noise generator 235 may provide (e.g., transmit) the random noise signal (e.g., or a random value sampled from the random noise signal) to a controller of the memory system 210 (e.g., the memory system controller 215, the local controller of the volatile memory device 220).

In other cases, the random noise generator 235 may be implemented within the host system 205 and the random noise signal (e.g., or a random value sampled from the random noise signal) may be provided to the memory system 210. In some such cases, the host system 205 may transmit the random noise signal to the memory system 210 via a pin 240 of the memory system 210, as described with reference to FIG. 2C. The memory system 210 may similarly communicate the random noise signal from the pin 240 to a controller of the memory system 210.

In some cases, prior to generating the random noise signal, the memory system 210 may perform a verification operation with the host system 205 to authenticate communication with the host system 205. In some such cases, the host system 205 and the memory system 210 may communicate verification indications (e.g., codes, authentication information, handshake information, identification information) via the pin 240. For example, the host system 205 may transmit a verification indication, and upon the memory system 210 authenticating that the verification information is valid, the memory system 210 may allow the host system 205 to transmit the random analog signal. In some cases, the memory system 210 and the host system 205 may communicate a start indication to initiate generating the random noise signal and a stop indication to cease generating the random noise signal. In some cases, the memory system 210 and the host system 205 may communicate timing indications associated with the random noise signal.

At 410, the random noise signal may be sampled to generate a value. For example, a voltage value corresponding to an amplitude of the random noise signal may be sampled. In cases where the random noise generator 235 is implemented at the host system 205, the random noise signal may be transmitted to the memory system 210 and the memory system 210 may sample the random noise signal. However, in other cases, the host system 205 may sample the random noise signal to generate the random value and then transmit the random value to the memory system 210.

At 415, the value may be mapped to a row address. For example, the row address may be mapped to the value based on a quantity of activations. That is, the voltage value may correspond to a quantity of activations, and the row address may correspond to the quantity of activations. The row address may be selected for use in a refresh operation based on mapping the row address to the value. The selected row address may be a random row address based on the randomness of the random noise signal and the randomness of the value.

At 420, the selected row address may be stored to a content addressable memory (e.g., a CAM, a temporary storage location). For example, the row address may be latched based on selecting the row address for use in the refresh operation.

At 425, the memory system 210 may optionally receive a refresh command to initialize the refresh operation. For example, the host system 205 may transmit a command indicating to refresh the volatile memory array. In some cases, the refresh command may be associated with a row hammer refresh operation. In some examples, the refresh command may be a read burst. The refresh command may be transmitted according to a periodic duration, or in response to monitored conditions of the memory system 210.

In other cases, the memory system 210 may initialize the refresh operation without receiving a command from the host system 205. For example, the refresh operation may be initiated based on a periodic duration, or in response to monitored conditions of the memory system 210.

At 430, the memory system 210 may identify row addresses adjacent to or nearby the selected row address. For example, the memory system 210 may identify the quantity of row addresses (e.g., 35 1, ±2, ±3, ±4, ±N, etc.) adjacent to or nearby the selected row address based on a threshold or a parameter. In some examples, the memory system 210 may identify a row corresponding to the selected row address, and identify the rows adjacent to or nearby the row (e.g., up to a numerical distance (N) away from the selected row). Then, the memory system 210 may identify the row addresses corresponding to the adjacent or nearby rows. For example, as illustrated in FIGS. 3A and 3B, the row address 14 may be identified based on sampling the analog signal. Then, the row addresses 13 and 15 may be identified for refresh operations.

At 435, the memory system 210 may refresh the adjacent or nearby rows addresses. In some cases, refreshing the nearby or adjacent row addresses may be defined by refreshing the rows corresponding to the nearby or adjacent row addresses. For example, as illustrated in FIGS. 3A and 3B, the rows corresponding to the row addresses 13 and 15 may be refreshed. Refreshing the adjacent or nearby row addresses may include refreshing the logic states of the memory cells in the corresponding rows. In some cases, after refreshing the adjacent or nearby row addresses, the memory system 210 may release the selected row address from the content addressable memory (e.g., remove the row address from the latch).

At 440, the memory system 210 may perform a verification operation to determine whether the row addresses corresponding to the sampled points of the random noise signal are truly random. In some cases, the verification operation may be used to verify row hammer functionality characterization for internal design verification. The memory system 210 may operate according to either of two modes for performing the verification operation, each of which includes operating counters for tracking the randomization of the selected row addresses. For example, the memory system 210 may implement a counter for each selected row address, such that the memory system 210 may track a count for each time a respective row address is selected according to the random noise signal.

In a first mode, the memory system 210 may increment the counter each time the row address is selected based on mapping the random noise signal to the row address. In a second mode, the memory system 210 may increment the counter each time the selected row address is released from the CAM. For both modes, the memory system 210 may read the counters and compare the count for each row address across the volatile memory array to determine whether the row addresses are truly. In some cases, the memory system 210 may determine the row addresses are not random and the memory system 210 may adjust one or more parameters or operating characteristics of the random noise generator 235, or transmit an indication to the host system 205 indicating the lack of randomization, which may result in the parameters or operating characteristics of the random noise generator 235 being adjusted. In some examples, the memory system 210 may indicate the lack of randomization and the host system 205 may transmit an indication to adjust the parameters or operating characteristics of the random noise generator 235. In some cases, a lack of randomization may be indicative of tampering by a bad actor, and an indication of suspected tampering by the bad actor may be communicated between the memory system 210 and the host system 205.

Implementing the random noise signal as described with reference to the process flow 400 may enable increased security for a system, such as the system 200-a and the system 200-b. For example, generating the random noise signal and mapping sampled points of the random noise signal to row addresses may counteract row hammering attacks from a bad actor. Further, because the random noise signal may be an analog signal, the bad actor may be less likely (or unable) to determine a pattern of randomization of the random noise signal, which the bad actor may otherwise use to perform the row hammering attacks.

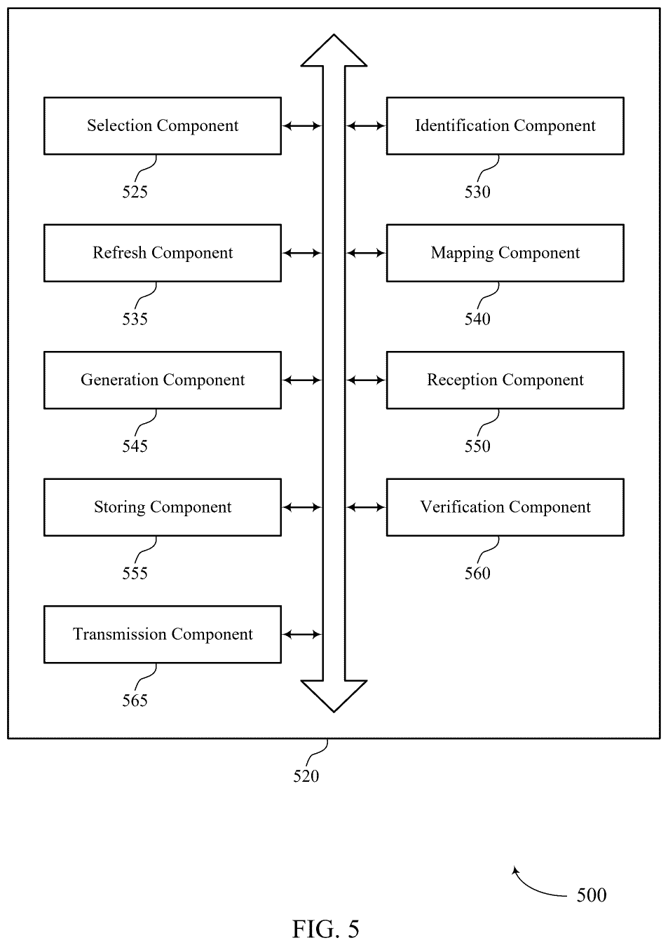

FIG. 5 shows a block diagram 500 of a memory system 520 that supports randomized refresh operations in accordance with examples as disclosed herein. The memory system 520 may be an example of aspects of a memory system as described with reference to FIGS. 1 through 4. The memory system 520, or various components thereof, may be an example of means for performing various aspects of randomized refresh operations as described herein. For example, the memory system 520 may include a selection component 525, an identification component 530, a refresh component 535, a mapping component 540, a generation component 545, a reception component 550, a storing component 555, a verification component 560, a transmission component 565, or any combination thereof. Each of these components, or components of subcomponents thereof (e.g., one or more processors, one or more memories), may communicate, directly or indirectly, with one another (e.g., via one or more buses).

The selection component 525 may be configured as or otherwise support a means for selecting a random value based at least in part on a random noise signal, where the random value is associated with a row address of a plurality of row addresses of a volatile memory array. The identification component 530 may be configured as or otherwise support a means for identifying, using the random value, a first row address of a volatile memory array based at least in part on selecting the random value. The refresh component 535 may be configured as or otherwise support a means for refreshing a second row address and a third row address of the volatile memory array based at least in part on identifying the first row address, where the second row address and the third row address are each adjacent to the first row address.

In some examples, the mapping component 540 may be configured as or otherwise support a means for mapping the random value to the first row address based at least in part on selecting the random value, where identifying the first row address is based at least in part on mapping the random value to the first row address.

In some examples, the generation component 545 may be configured as or otherwise support a means for generating, by a random noise generator, the random noise signal, where selecting the random value is based at least in part on generating the random noise signal.

In some examples, the reception component 550 may be configured as or otherwise support a means for receiving, from a host device, the random noise signal via a pin, where selecting the random value is based at least in part on receiving the random noise signal.

In some examples, the transmission component 565 may be configured as or otherwise support a means for transmitting a first signal to the host device via the pin. In some examples, the reception component 550 may be configured as or otherwise support a means for receiving a second signal from the host device via the pin based at least in part on transmitting the first signal to the host device, where selecting the random value is based at least in part on receiving the second signal from the host device.

In some examples, the storing component 555 may be configured as or otherwise support a means for storing the first row address to a content addressable memory (CAM) based at least in part on identifying the first row address, where refreshing the second row address and the third row address is based at least in part on storing the first row address to the CAM.

In some examples, the reception component 550 may be configured as or otherwise support a means for receiving, after storing the first row address to the CAM, a refresh command, where refreshing the second row address and the third row address is based at least in part on storing the first row address to the CAM and receiving the refresh command.

In some examples, the verification component 560 may be configured as or otherwise support a means for removing the first row address from the CAM. In some examples, the verification component 560 may be configured as or otherwise support a means for incrementing a counter associated with the first row address based at least in part on removing the first row address from the CAM. In some examples, the verification component 560 may be configured as or otherwise support a means for reading a value of the counter based at least in part on refreshing the second row address and the third row address. In some examples, the verification component 560 may be configured as or otherwise support a means for performing a validation operation based at least in part on reading the value of the counter.

In some examples, the identification component 530 may be configured as or otherwise support a means for identifying the second row address and the third row address based at least in part on identifying the first row address, where refreshing the second row address and the third row address is based at least in part on identifying the second row address and the third row address.

In some examples, the random noise signal includes an analog signal, and the identification component 530 may be configured as or otherwise support a means for identifying a value of the analog signal. In some examples, the random noise signal includes an analog signal, and the selection component 525 may be configured as or otherwise support a means for selecting the random value based at least in part on the value of the analog signal.

In some examples, to support refreshing the second row address and the third row address, the refresh component 535 may be configured as or otherwise support a means for refreshing a second row of memory cells and a third row of memory cells of the volatile memory array, where the second row of memory cells and the third row of memory cells are adjacent to a first row of memory cells that is associated with the first row address.

In some examples, the verification component 560 may be configured as or otherwise support a means for incrementing a counter associated with the first row address based at least in part on identifying the first row address. In some examples, the verification component 560 may be configured as or otherwise support a means for reading a value of the counter based at least in part on refreshing the second row address and the third row address. In some examples, the verification component 560 may be configured as or otherwise support a means for performing a validation operation based at least in part on reading the value of the counter.

In some examples, the described functionality of the memory system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

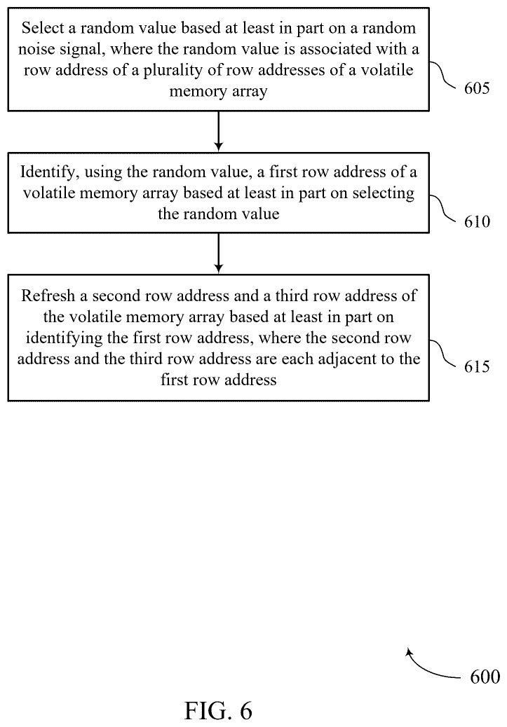

FIG. 6 shows a flowchart illustrating a method 600 that supports randomized refresh operations in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include selecting a random value based at least in part on a random noise signal, where the random value is associated with a row address of a plurality of row addresses of a volatile memory array. In some examples, aspects of the operations of 605 may be performed by a selection component 525 as described with reference to FIG. 5.

At 610, the method may include identifying, using the random value, a first row address of a volatile memory array based at least in part on selecting the random value. In some examples, aspects of the operations of 610 may be performed by an identification component 530 as described with reference to FIG. 5.

At 615, the method may include refreshing a second row address and a third row address of the volatile memory array based at least in part on identifying the first row address, where the second row address and the third row address are each adjacent to the first row address. In some examples, aspects of the operations of 615 may be performed by a refresh component 535 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for selecting a random value based at least in part on a random noise signal, where the random value is associated with a row address of a plurality of row addresses of a volatile memory array; identifying, using the random value, a first row address of a volatile memory array based at least in part on selecting the random value; and refreshing a second row address and a third row address of the volatile memory array based at least in part on identifying the first row address, where the second row address and the third row address are each adjacent to the first row address.
Aspect 2: The method, apparatus, or non-transitory computer-readable medium of aspect 1, further including operations, features, circuitry, logic, means, or instructions, or any combination thereof for mapping the random value to the first row address based at least in part on selecting the random value, where identifying the first row address is based at least in part on mapping the random value to the first row address.
Aspect 3: The method, apparatus, or non-transitory computer-readable medium of any of aspects 1 through 2, further including operations, features, circuitry, logic, means, or instructions, or any combination thereof for generating, by a random noise generator, the random noise signal, where selecting the random value is based at least in part on generating the random noise signal.
Aspect 4: The method, apparatus, or non-transitory computer-readable medium of any of aspects 1 through 3, further including operations, features, circuitry, logic, means, or instructions, or any combination thereof for receiving, from a host device, the random noise signal via a pin, where selecting the random value is based at least in part on receiving the random noise signal.
Aspect 5: The method, apparatus, or non-transitory computer-readable medium of aspect 4, further including operations, features, circuitry, logic, means, or instructions, or any combination thereof for transmitting a first signal to the host device via the pin and receiving a second signal from the host device via the pin based at least in part on transmitting the first signal to the host device, where selecting the random value is based at least in part on receiving the second signal from the host device.
Aspect 6: The method, apparatus, or non-transitory computer-readable medium of any of aspects 1 through 5, further including operations, features, circuitry, logic, means, or instructions, or any combination thereof for storing the first row address to a content addressable memory (CAM) based at least in part on identifying the first row address, where refreshing the second row address and the third row address is based at least in part on storing the first row address to the CAM.
Aspect 7: The method, apparatus, or non-transitory computer-readable medium of aspect 6, further including operations, features, circuitry, logic, means, or instructions, or any combination thereof for receiving, after storing the first row address to the CAM, a refresh command, where refreshing the second row address and the third row address is based at least in part on storing the first row address to the CAM and receiving the refresh command.
Aspect 8: The method, apparatus, or non-transitory computer-readable medium of any of aspects 6 through 7, further including operations, features, circuitry, logic, means, or instructions, or any combination thereof for removing the first row address from the CAM; incrementing a counter associated with the first row address based at least in part on removing the first row address from the CAM; reading a value of the counter based at least in part on refreshing the second row address and the third row address; and performing a validation operation based at least in part on reading the value of the counter.
Aspect 9: The method, apparatus, or non-transitory computer-readable medium of any of aspects 1 through 8, further including operations, features, circuitry, logic, means, or instructions, or any combination thereof for identifying the second row address and the third row address based at least in part on identifying the first row address, where refreshing the second row address and the third row address is based at least in part on identifying the second row address and the third row address.
Aspect 10: The method, apparatus, or non-transitory computer-readable medium of any of aspects 1 through 9, where the random noise signal includes an analog signal and the method, apparatuses, and non-transitory computer-readable medium further includes operations, features, circuitry, logic, means, or instructions, or any combination thereof for identifying a value of the analog signal and selecting the random value based at least in part on the value of the analog signal.
Aspect 11: The method, apparatus, or non-transitory computer-readable medium of any of aspects 1 through 10, where refreshing the second row address and the third row address includes operations, features, circuitry, logic, means, or instructions, or any combination thereof for refreshing a second row of memory cells and a third row of memory cells of the volatile memory array, where the second row of memory cells and the third row of memory cells are adjacent to a first row of memory cells that is associated with the first row address.
Aspect 12: The method, apparatus, or non-transitory computer-readable medium of any of aspects 1 through 11, further including operations, features, circuitry, logic, means, or instructions, or any combination thereof for incrementing a counter associated with the first row address based at least in part on identifying the first row address; reading a value of the counter based at least in part on refreshing the second row address and the third row address; and performing a validation operation based at least in part on reading the value of the counter.

It should be noted that the aspects described herein describe possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processor. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, that can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or a processor.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
select a random value based at least in part on a random noise signal, wherein the random value is associated with a row address of a plurality of row addresses of a volatile memory array;
identify, using the random value, a first row address of the volatile memory array based at least in part on selecting the random value; and
refresh a second row address and a third row address of the volatile memory array based at least in part on identifying the first row address, wherein the second row address and the third row address are each adjacent to the first row address.

2. The memory system of claim 1, wherein the processing circuitry is further configured to cause the memory system to:
map the random value to the first row address based at least in part on selecting the random value, wherein identifying the first row address is based at least in part on mapping the random value to the first row address.

3. The memory system of claim 1, wherein the processing circuitry is further configured to cause the memory system to:
generate, by a random noise generator, the random noise signal, wherein selecting the random value is based at least in part on generating the random noise signal.

4. The memory system of claim 1, wherein the processing circuitry is further configured to cause the memory system to:
receive, from a host device, the random noise signal via a pin, wherein selecting the random value is based at least in part on receiving the random noise signal.

5. The memory system of claim 4, wherein the processing circuitry is further configured to cause the memory system to:
transmit a first signal to the host device via the pin; and
receive a second signal from the host device via the pin based at least in part on transmitting the first signal to the host device, wherein selecting the random value is based at least in part on receiving the second signal from the host device.

6. The memory system of claim 1, wherein the processing circuitry is further configured to cause the memory system to:
store the first row address to a content addressable memory (CAM) based at least in part on identifying the first row address,
wherein refreshing the second row address and the third row address is based at least in part on storing the first row address to the CAM.

7. The memory system of claim 6, wherein the processing circuitry is further configured to cause the memory system to:
receive, after storing the first row address to the CAM, a refresh command,
wherein refreshing the second row address and the third row address is based at least in part on storing the first row address to the CAM and receiving the refresh command.

8. The memory system of claim 6, wherein the processing circuitry is further configured to cause the memory system to:
remove the first row address from the CAM;
increment a counter associated with the first row address based at least in part on removing the first row address from the CAM;
read a value of the counter based at least in part on refreshing the second row address and the third row address; and
perform a validation operation based at least in part on reading the value of the counter.

9. The memory system of claim 1, wherein the processing circuitry is further configured to cause the memory system to:
identify the second row address and the third row address based at least in part on identifying the first row address, wherein refreshing the second row address and the third row address is based at least in part on identifying the second row address and the third row address.

10. The memory system of claim 1, wherein the random noise signal comprises an analog signal, and the processing circuitry is further configured to cause the memory system to:
identify a value of the analog signal; and
select the random value based at least in part on the value of the analog signal.

11. The memory system of claim 1, wherein refreshing the second row address and the third row address comprises the processing circuitry configured to cause the memory system to refresh a second row of memory cells and a third row of memory cells of the volatile memory array, wherein the second row of memory cells and the third row of memory cells are adjacent to a first row of memory cells that is associated with the first row address.

12. The memory system of claim 1, wherein the processing circuitry is further configured to cause the memory system to:
increment a counter associated with the first row address based at least in part on identifying the first row address;
read a value of the counter based at least in part on refreshing the second row address and the third row address; and
perform a validation operation based at least in part on reading the value of the counter.

13. A non-transitory computer-readable medium storing code, the code comprising instructions executable by one or more processors to:
select a random value based at least in part on a random noise signal, wherein the random value is associated with a row address of a plurality of row addresses of a volatile memory array;
identify, using the random value, a first row address of the volatile memory array based at least in part on selecting the random value; and
refresh a second row address and a third row address of the volatile memory array based at least in part on identifying the first row address, wherein the second row address and the third row address are each adjacent to the first row address.

14. The non-transitory computer-readable medium of claim 13, wherein the instructions are further executable by the one or more processors to:
map the random value to the first row address based at least in part on selecting the random value, wherein identifying the first row address is based at least in part on mapping the random value to the first row address.

15. The non-transitory computer-readable medium of claim 13, wherein the instructions are further executable by the one or more processors to:
generate, by a random noise generator, the random noise signal, wherein selecting the random value is based at least in part on generating the random noise signal.

16. The non-transitory computer-readable medium of claim 13, wherein the instructions are further executable by the one or more processors to:
receive, from a host device, the random noise signal via a pin, wherein selecting the random value is based at least in part on receiving the random noise signal.

17. The non-transitory computer-readable medium of claim 16, wherein the instructions are further executable by the one or more processors to:
transmit a first signal to the host device via the pin; and
receive a second signal from the host device via the pin based at least in part on transmitting the first signal to the host device, wherein selecting the random value is based at least in part on receiving the second signal from the host device.

18. The non-transitory computer-readable medium of claim 13, wherein the instructions are further executable by the one or more processors to:
store the first row address to a content addressable memory (CAM) based at least in part on identifying the first row address; and
receive, after storing the first row address to the CAM, a refresh command,
wherein refreshing the second row address and the third row address is based at least in part on storing the first row address to the CAM and receiving the refresh command.

19. The non-transitory computer-readable medium of claim 13, wherein the instructions are further executable by the one or more processors to:
identify the second row address and the third row address based at least in part on identifying the first row address, wherein refreshing the second row address and the third row address is based at least in part on identifying the second row address and the third row address.

20. A method by a memory system, comprising:
selecting a random value based at least in part on a random noise signal, wherein the random value is associated with a row address of a plurality of row addresses of a volatile memory array;
identifying, using the random value, a first row address of the volatile memory array based at least in part on selecting the random value; and
refreshing a second row address and a third row address of the volatile memory array based at least in part on identifying the first row address, wherein the second row address and the third row address are each adjacent to the first row address.
